(19) United States
(12) Patent Application Publication
(10) Pub. No.: US 2018/0240702 A1
(43) Pub. Date: Aug. 23, 2018

(54) SEMICONDUCTOR DEVICE AND METHOD FOR MANUFACTURING SAME

(71) Applicant: Toshiba Memory Corporation, Minato-ku (JP)

(72) Inventor: Katsumi MORII, Yokkaichi (JP)

(73) Assignee: Toshiba Memory Corporation, Minato-ku (JP)

(21) Appl. No.: 15/695,267

(22) Filed: Sep. 5, 2017

(30) Foreign Application Priority Data
Feb. 21, 2017 (JP) 2017 -029651

(51) Int. Cl. H01L 21/768; H01L 27/11524; H01L 27/11556; H01L 27/1157; H01L 27/11582; H01L 23/522; H01L 23/532; H01L 21/285

(52) U.S. Cl. CPC H01L 21/76877; H01L 27/11524; H01L 27/11556; H01L 27/1157; H01L 21/28556; H01L 23/5226; H01L 23/53257; H01L 21/76802; H01L 27/11582

(57) ABSTRACT

According to one embodiment, a stacked body includes a plurality of conductive layers stacked with an insulator interposed. A semiconductor body extends in the stacked body in a stacking direction of the stacked body. A charge storage portion is provided between the semiconductor body and one of the conductive layers. A silicon oxide film is provided between the charge storage portion and the one of the conductive layers. A silicon nitride film is provided between the silicon oxide film and the one of the conductive layers.

### CROSS-REFERENCE TO RELATED APPLICATION

This application is based upon and claims the benefit of priority from Japanese Patent Application No. 2017-029651, filed on Feb. 21, 2017; the entire contents of which are incorporated herein by reference.

### FIELD

Embodiments described herein relate generally to a semiconductor device and a method for manufacturing a semiconductor device.

### BACKGROUND

As a method for forming an electrode layer which functions as a control gate of a three-dimensional memory device, a method in which a gap is formed by removing a sacrifice layer formed between insulating layers and a metal layer is formed in the gap has been proposed.

### BRIEF DESCRIPTION OF THE DRAWINGS

FIG. 1 is a schematic perspective view of a semiconductor device of an embodiment;

FIG. 2 is a schematic sectional view of the semiconductor device of the embodiment;

FIGS. 3A to 3C are enlarged views of a portion A in FIG. 2;

FIG. 4 to FIG. 16C are schematic sectional views showing a method for manufacturing the semiconductor device of the embodiment; and

FIG. 17 is a schematic perspective view of a semiconductor device of the embodiment.

### DETAILED DESCRIPTION

According to one embodiment, a semiconductor device includes a foundation layer, a stacked body provided above the foundation layer, the stacked body including a plurality of conductive layers stacked with an insulator interposed, a semiconductor body extending in the stacked body in a stacking direction of the stacked body, a charge storage portion provided between the semiconductor body and one of the conductive layers, a silicon oxide film provided between the charge storage portion and the one of the conductive layers, and a silicon nitride film provided between the silicon oxide film and the one of the conductive layers.

Embodiments are described below with reference to the drawings. In the drawings, the same components are denoted by the same reference numerals and signs.

For example, a semiconductor memory device that includes a memory cell array having a three-dimensional structure is described as a semiconductor device in the embodiment.

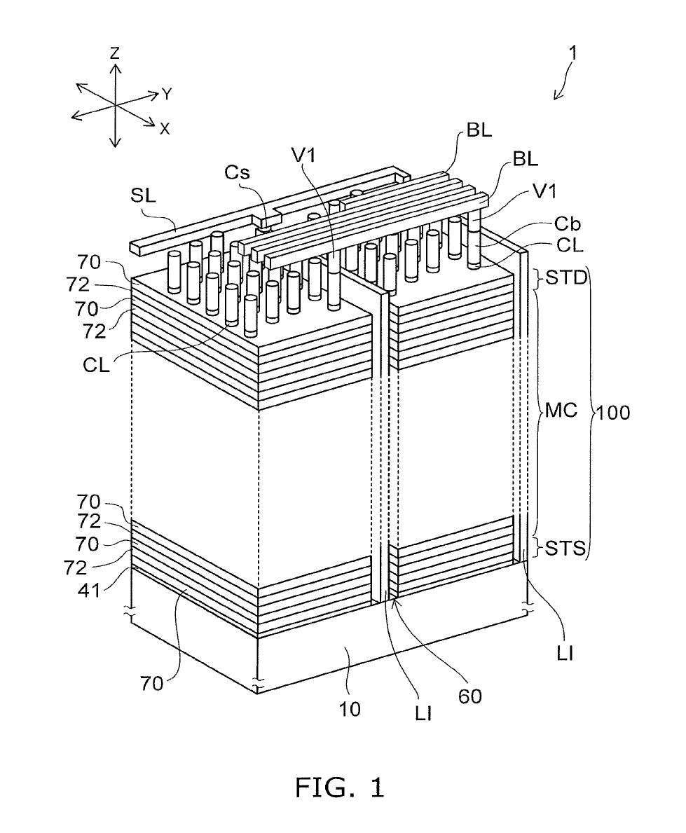

FIG. 1 is a schematic perspective view of a memory cell array 1 of the embodiment.

In FIG. 1, two directions that are parallel to a major surface of a substrate 10 and orthogonal to each other are defined as an X-direction and a Y-direction, and a direction that is orthogonal to the X-direction and the Y-direction is defined as a Z-direction (stacking direction).

The memory cell array 1 includes the substrate 10, a stacked body 100 stacked on the major surface of the substrate 10, a plurality of columnar portions CL, a plurality of dividing portions 60, and an upper layer interconnect provided above the stacked body 100. In FIG. 1, as the upper layer interconnect, for example, a bit liner BL and a source line SL are shown.

The columnar portion CL is formed in a substantially circular columnar shape extending in the stacked body 100 in the stacking direction (Z-direction). The dividing portion 60 includes an interconnect portion LI spreading in the stacking direction (Z-direction) of the stacked body 100 and in the X-direction, and divides the stacked body 100 into a plurality of blocks (or fingers) in the Y-direction.

A plurality of columnar portions CL is disposed in, for example, a staggered arrangement. Alternatively, the plurality of columnar portions CL may be disposed in a square grid pattern along the X-direction and the Y-direction.

Above the stacked body 100, a plurality of bit lines BL is provided. The plurality of bit lines BL is, for example, a metal film extending in the Y-direction. The plurality of bit lines BL is separated from each other in the X-direction.

An upper end of the below-mentioned semiconductor body of the columnar portion CL is connected to the bit line BL through contact portions Cb and V1. The plurality of columnar portions CL is connected to one common bit line BL. The plurality of columnar portions CL connected to the common bit line BL includes columnar portions CL selected one by one from each block divided in the Y-direction by the dividing portion 60.

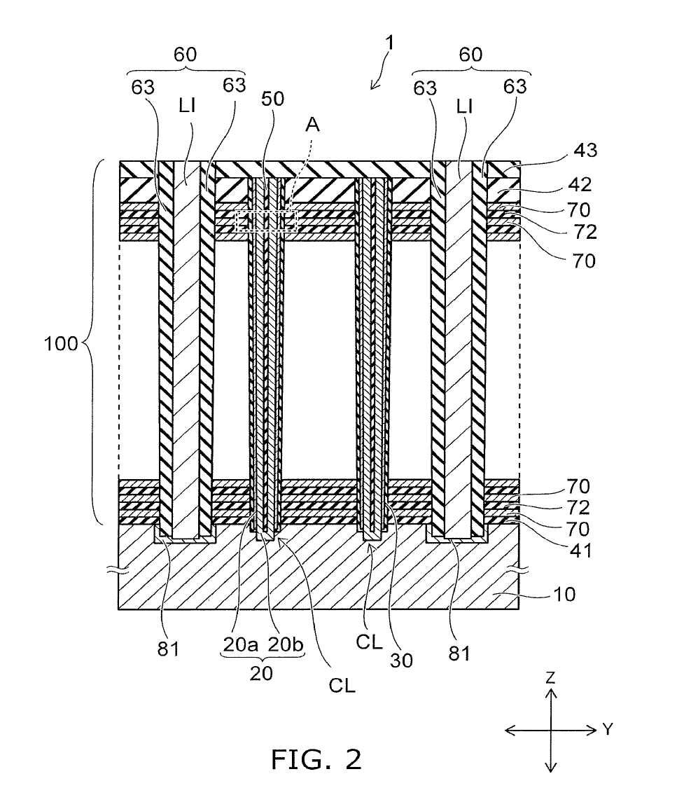

FIG. 2 is a schematic sectional view of the memory cell array 1. The Y-direction and the Z-direction shown in FIG. 2 correspond to the Y-direction and the Z-direction shown in FIG. 1, respectively.

The stacked body 100 includes a plurality of conductive layers 70 stacked on the major surface of the substrate 10 as a foundation layer. The plurality of conductive layers 70 is stacked in a direction (Z-direction) perpendicular to the major surface of the substrate 10 with an insulating layer 72 as an insulator interposed.

The conductive layer 70 is a metal layer, and is, for example, a tungsten layer or a molybdenum layer. The insulating layer 72 is, for example, a silicon oxide layer. Incidentally, the insulator between the conductive layers 70 vertically adjacent to each other may be a gap (air gap).

Between the major surface of the substrate 10 and the conductive layer 70 being the lowermost layer, an insulating film 41 is provided. On the conductive layer 70 being the uppermost layer, an insulating film 42 is provided, and on the insulating film 42, an insulating film 43 is provided.

The columnar portion CL includes a memory film (stacked film) 30, a semiconductor body 20, and a core film 50 having an insulating property.

The semiconductor body 20 extends in a pipe shape in the stacking direction (Z-direction) in the stacked body 100. The memory film 30 is provided between the conductive layer and the semiconductor body 20 and surrounds the semiconductor body 20 from an outer circumference. The core film 50 is provided inside the semiconductor body 20 in a pipe shape. An upper end of the semiconductor body 20 is connected to the bit line BL through the contact portions Cb and V1 shown in FIG. 1.

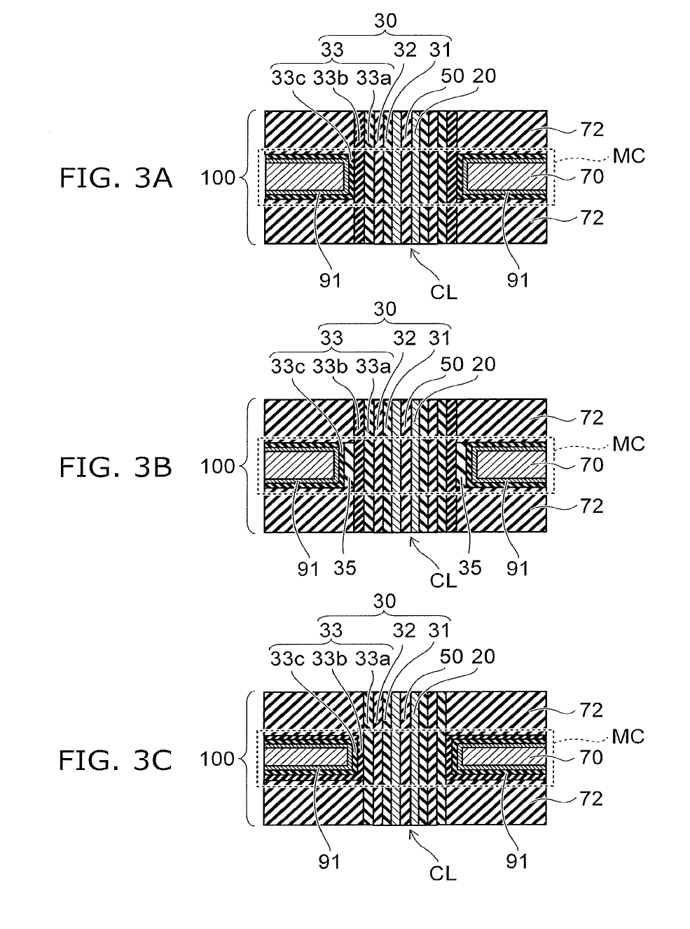

FIG. 3A is an enlarged view of a portion A in FIG. 2.

The memory film 30 is a stacked film including a tunnel insulating film 31, a charge storage film (charge storage portion) 32, and a block insulating film 33. Between the conductive layer 70 and the semiconductor body 20, the block insulating film 33, the charge storage film 32, and the tunnel insulating film 31 are provided sequentially from the conductive layer 70. The tunnel insulating film 31 is in contact with the semiconductor body 20. The charge storage film 32 is provided between the block insulating film 33 and the tunnel insulating film 31. The tunnel insulating film 31 and the charge storage film 32 extend continuously in the stacking direction of the stacked body 100.

The semiconductor body 20, the memory film 30, and the conductive layer 70 constitute the memory cell MC. In FIG. 3A, one memory cell MC is schematically shown by a broken line. The memory cell MC has a vertical transistor structure in which the circumference of the semiconductor body 20 is surrounded by the conductive layer 70 through the memory film 30.

In the memory cell MC having a vertical transistor structure, the semiconductor body 20 is, for example, a silicon channel body, and the conductive layer 70 functions as a control gate. The charge storage film 32 functions as a data storage layer which stores electric charges injected from the semiconductor body 20.

The semiconductor memory device of the embodiment is a non-volatile semiconductor memory device capable of electrically erasing and writing data freely, and holding storage contents even after the power is turned off.

The memory cell MC is, for example, a charge trapping memory cell. The charge storage film 32 has a lot of trap sites for trapping electric charges in a film having an insulating property, and includes, for example, a silicon nitride film. Alternatively, the charge storage film (charge storage portion) 32 may be a floating gate having electrical conductivity and surrounded by an insulator.

The tunnel insulating film 31 serves as a potential barrier when electric charges are injected from the semiconductor body 20 to the charge storage film 32 or when electric charges stored in the charge storage film 32 are released to the semiconductor body 20. The tunnel insulating film 31 includes, for example, a silicon oxide film.

The block insulating film 33 includes a silicon oxide film 33a, a silicon nitride film 33b, and a metal oxide film 33c. The silicon oxide film 33a is in contact with the charge storage film 32, and extends continuously in the stacking direction of the stacked body 100. The silicon nitride film 33b is provided between the metal oxide film 33c and the silicon oxide film 33a, and between the insulating layer 72 and the silicon oxide film 33a, and extends continuously in the stacking direction of the stacked body 100.

The silicon oxide film 33a prevents electric charges stored in the charge storage film 32 from diffusing into the conductive layer 70.

The metal oxide film 33c is provided between the conductive layer 70 and the silicon nitride film 33b, and is in contact with the silicon nitride film 33b. The metal oxide film 33c is also provided between the conductive layer 70 and the insulating layer 72. The metal oxide film 33c has a higher dielectric constant than the silicon oxide film 33a and the silicon nitride film 33b, and is, for example, an aluminum oxide film.

For example, in a data erasing operation, the metal oxide film 33c relaxes the electric field between the conductive layer 70 and the semiconductor body 20, and reduces energy of electrons back tunneling from the conductive layer 70 to the columnar portion CL.

Between the conductive layer 70 and the metal oxide film 33c, a metal nitride film 91 is provided. The metal nitride film 91 is, for example, a titanium nitride film. The metal nitride film 91 is continuous along the upper surface, the lower surface, and the side surface on a side of the columnar portion CL of the conductive layer 70, and is in contact with these upper surface, lower surface, and side surface of the conductive layer 70.

As shown in FIG. 1, in an upper layer portion of the stacked body 100, a drain-side select transistor STD is provided, and in a lower layer portion of the stacked body 100, a source-side select transistor STS is provided. At least the conductive layer 70 being the uppermost layer functions as a control gate of the drain-side select transistor STD. At least the conductive layer 70 being the lowermost layer functions as a control gate of the source-side select transistor STS.

Between the drain-side select transistor STD and the source-side select transistor STS, a plurality of memory cells MC is provided. The plurality of memory cells MC, the drain-side select transistor STD, and the source-side select transistor STS are connected in series through the semiconductor body 20 and constitutes one memory string. This memory string is disposed in a plane direction parallel to an X-Y plane, for example, in a staggered arrangement, and a plurality of memory cells MC is provided three-dimensionally in the X-direction, the Y-direction, and the Z-direction.

As shown in FIG. 1, the interconnect portion LI spreads in the X-direction and the Z-direction, and is, for example, a film containing a metal. On the side surface of the interconnect portion LI, as shown in FIG. 2, an insulating film 63 is provided. The insulating film 63 is provided between the stacked body 100 and the interconnect portion LI.

An upper end of the interconnect portion LI is connected to the source line SL through contact portion Cs shown in FIG. 1.

A lower end of the interconnect portion LI is in contact with the substrate 10. Further, a lower end of the semiconductor body 20 is in contact with the substrate 10. The substrate 10 is, for example, a silicon substrate doped with an impurity and having electrical conductivity.

On the surface of the substrate 10 which the lower end of the interconnect portion LI reaches, as shown in FIG. 2, a semiconductor region 81 is formed. A plurality of semiconductor regions 81 is provided corresponding to a plurality of interconnect portions LI. In a reading operation, electrons are supplied to the semiconductor body 20 from the interconnect portion LI through the n-type semiconductor region 81 and the substrate 10.

By controlling a potential applied to the conductive layer 70 being the lowermost layer provided on the surface (major surface) of the substrate 10 through the insulating film 41, a channel is induced on the surface of the substrate 10 between the semiconductor region 81 and the lower end of the semiconductor body 20, and a current can be allowed to flow between the semiconductor region 81 and the lower end of the semiconductor body 20.

The conductive layer 70 being the lowermost layer functions as a control gate for inducing a channel on the surface of the substrate 10, and the insulating film 41 functions as a gate insulating film.

According to the embodiment, the silicon nitride film 33b included in the block insulating film 33 blocks diffusion of an element (for example, fluorine) other than the main component metal contained in the conductive layer 70 into a side of the insulating layer 72 and the silicon oxide film 33a as will be described later.

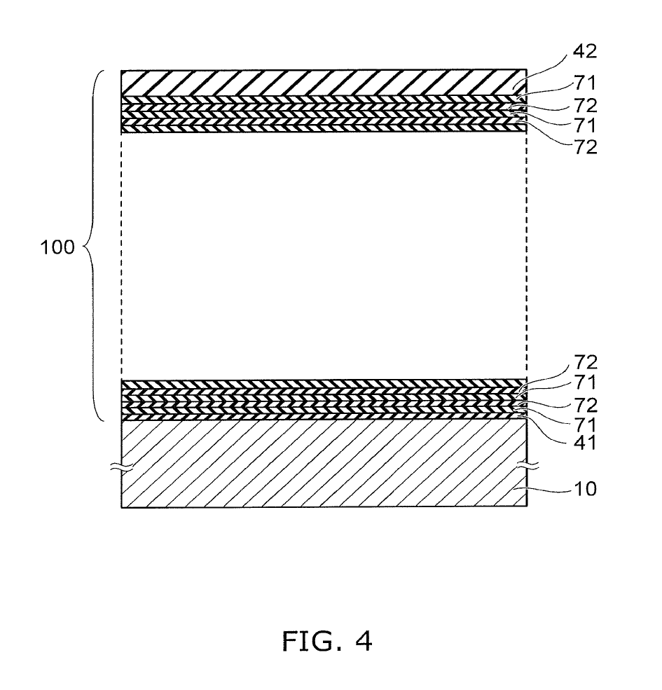

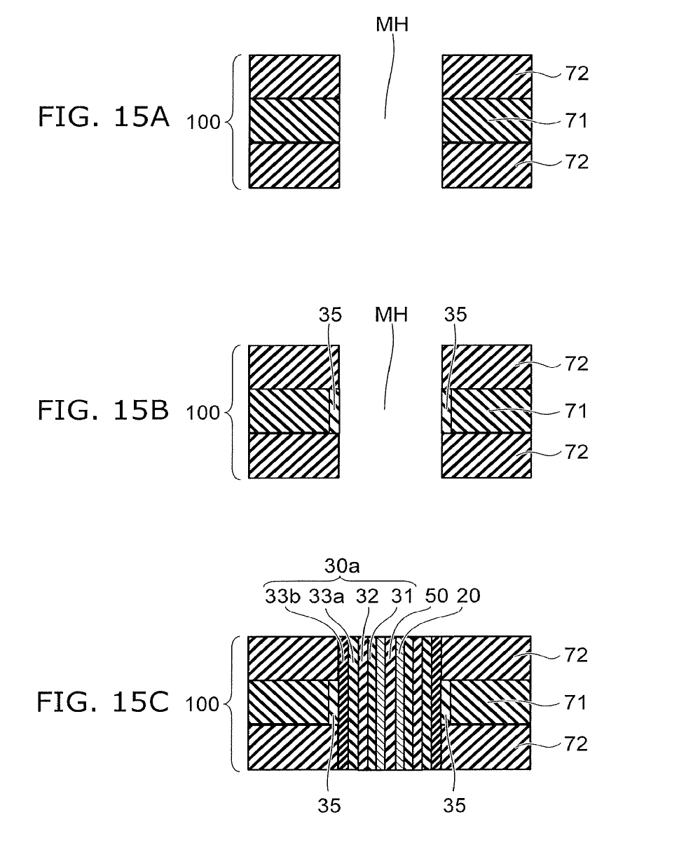

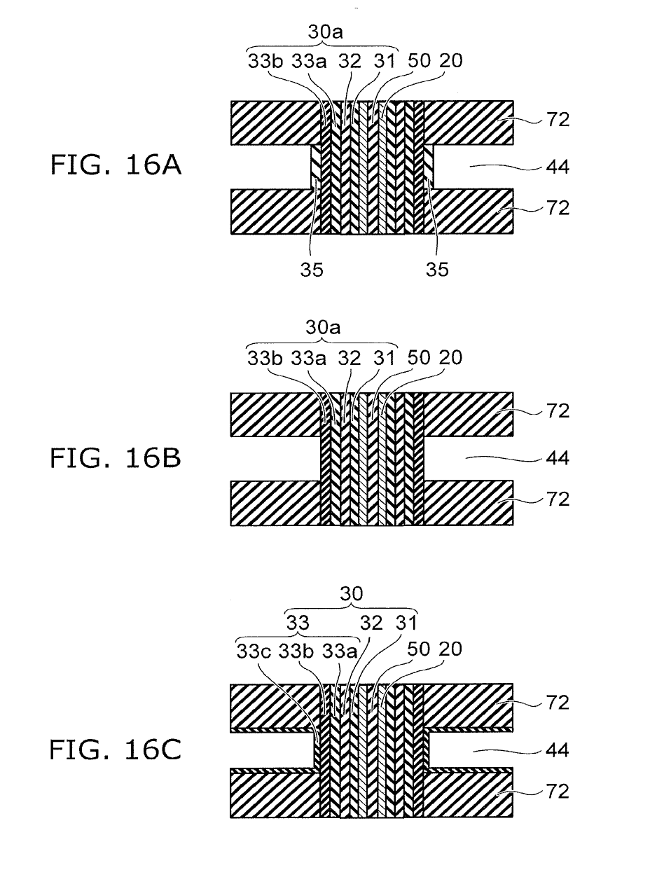

Next, a method for manufacturing the semiconductor device of the embodiment will be described with reference to FIG. 4 to FIG. 16C. FIG. 15A to FIG. 16C are partially enlarged sectional views of the stacked body 100.

As shown in FIG. 4, the stacked body 100 is formed on the substrate 10 as the foundation layer. The insulating film 41 is formed on the major surface (surface) of the substrate 10, and on the insulating film 41, a sacrifice layer 71 as the first layer and the insulating layer 72 as the second layer are alternately stacked. A process of alternately stacking the sacrifice layer 71 and the insulating layer 72 is repeated, whereby a plurality of sacrifice layers 71 and a plurality of insulating layers 72 are formed on the substrate 10. For example, the sacrifice layer 71 is a silicon nitride layer, and the insulating layer 72 is a silicon oxide layer.

On the insulating film 41, the sacrifice layer 71 being the lowermost layer is formed, and on the sacrifice layer 71 being the lowermost layer, the insulating layer 72 being the lowermost layer is formed. On the sacrifice layer 71 being the uppermost layer, the insulating film 42 is formed.

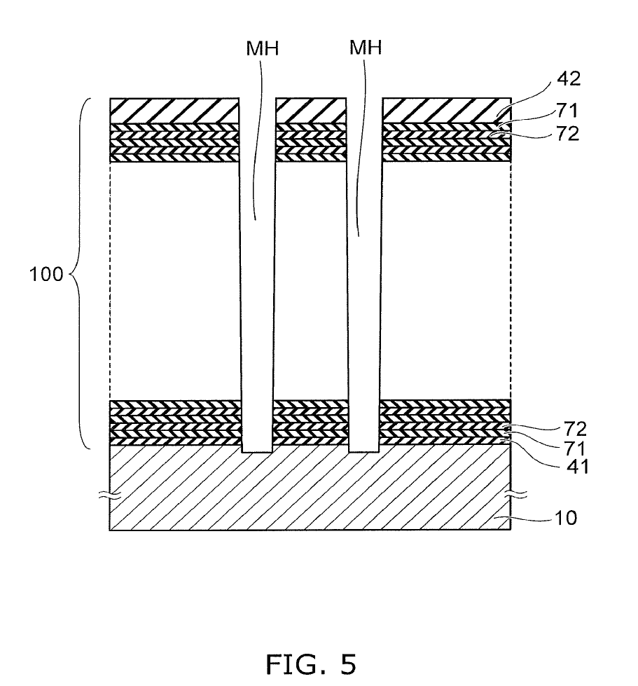

Subsequently, as shown in FIG. 5 and FIG. 15A, a plurality of memory holes MH is formed in the stacked body 100. The memory hole MH is formed by a reactive ion etching (RIE) method using a mask (not shown). The memory hole MH extends in the stacking direction (Z-direction) of the stacked body 100 and reaches the substrate 10.

In an end portion of the sacrifice layer 71 exposed in the memory hole MH, as shown in FIG. 15B, a silicon oxide portion (cover oxide film) 35 is formed. For example, the end portion of the sacrifice layer 71 which is a silicon nitride layer is oxidized. Alternatively, in the end portion of the sacrifice layer 71, a silicon oxide film may be formed. Before forming this silicon oxide film, the end portion of the sacrifice layer 71 may be retreated, or the silicon oxide film may be formed directly without retreating the end portion of the sacrifice layer 71.

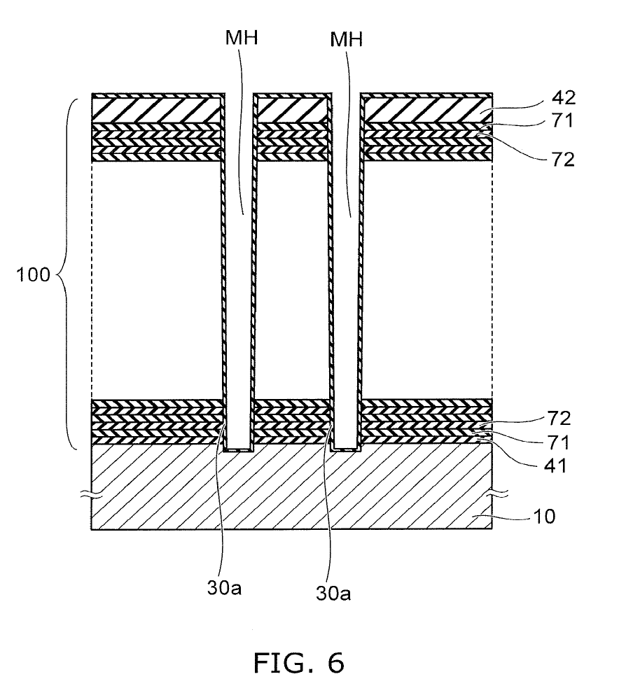

After forming the silicon oxide portion 35, in the memory hole MH, as shown in FIG. 6, a stacked film 30a is formed. The stacked film 30a includes the silicon nitride film 33b, the silicon oxide film 33a, the charge storage film 32, and the tunnel insulating film 31 in the memory film 30 shown in FIG. 3A. The stacked film 30a is formed conformally along the side surface and the bottom of the memory hole MH.

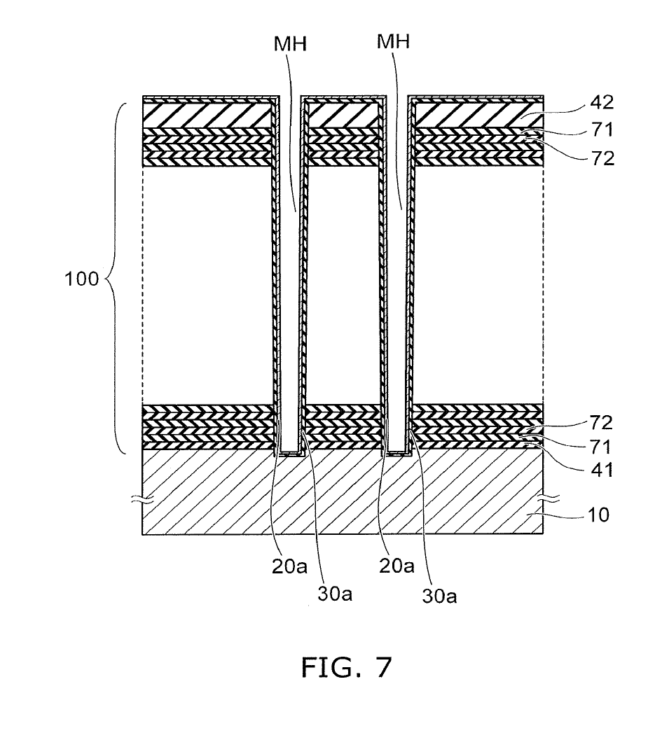

Inside the stacked film 30a, as shown in FIG. 7, a cover film 20a is formed. The cover film 20a is formed conformally along the side surface and the bottom of the memory hole MH.

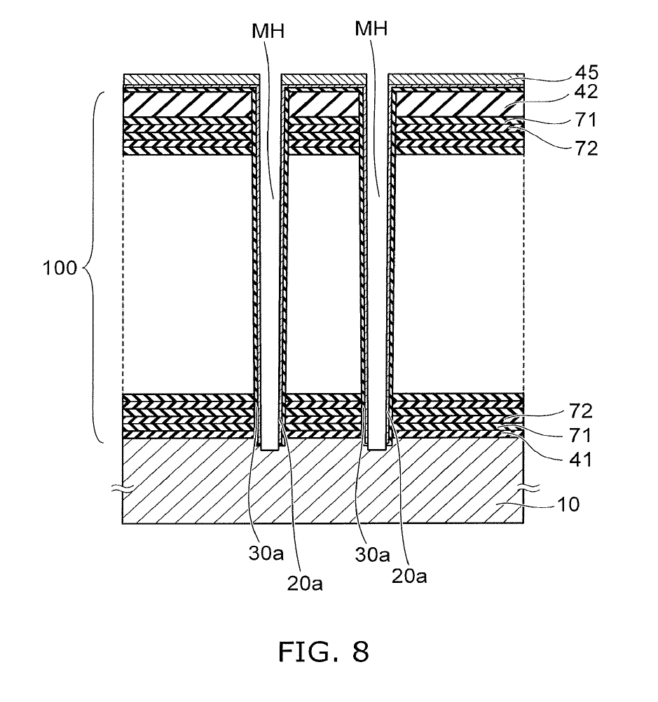

Then, as shown in FIG. 8, a mask layer 45 is formed on the upper surface of the stacked body 100, and the cover film 20a and the stacked film 30a deposited on the bottom of the memory hole MH are removed by an RIE method. During this RIE, the stacked film 30a formed on the side surface of the memory hole MH is protected by being covered with the cover film 20a, and is not damaged by RIE.

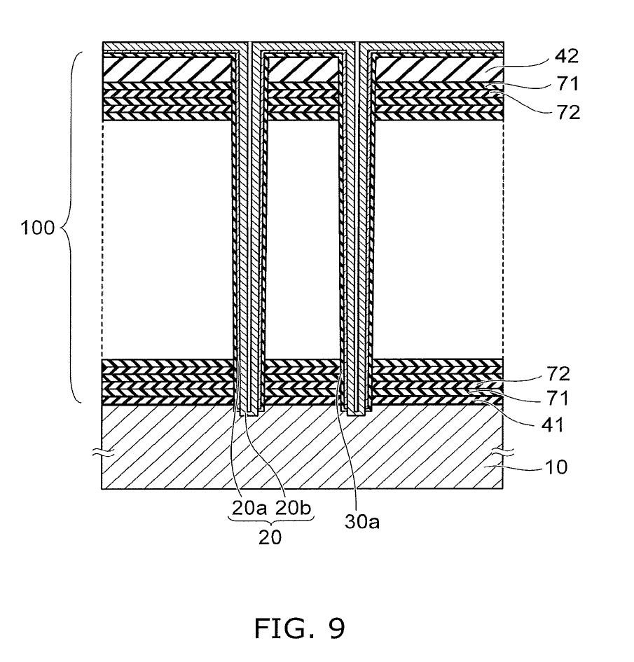

After removing the mask layer 45, as shown in FIG. 9, a semiconductor film 20b is formed in the memory hole MH. The semiconductor film 20b is formed on the side surface of the cover film 20a, and the bottom of the memory hole MH in which the substrate 10 is exposed.

The cover film 20a and the semiconductor film 20b are each formed as, for example, an amorphous silicon film, followed by crystallization into a polycrystalline silicon film by a heat treatment. The cover film 20a and the semiconductor film 20b constitute the above-mentioned semiconductor body 20.

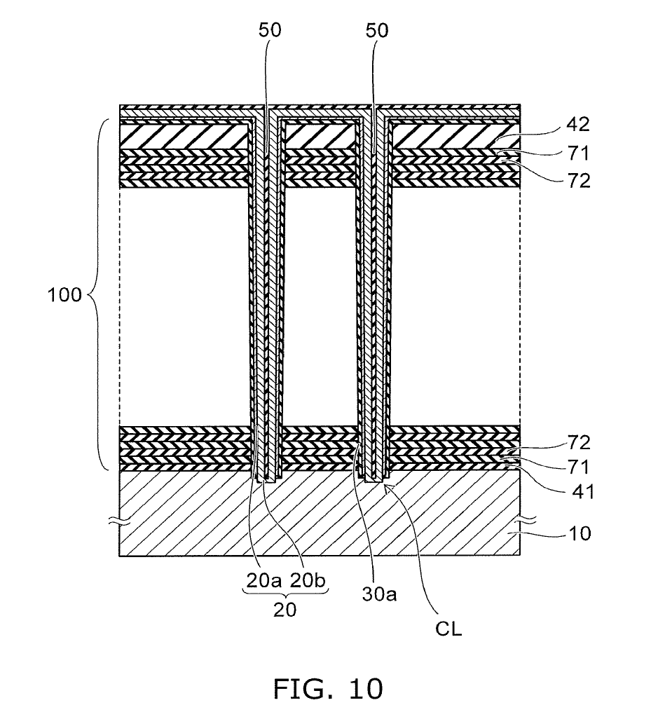

Inside the semiconductor film 20b, as shown in FIG. 10, the core film 50 is formed. In this manner, as shown in FIG. 10 and FIG. 15C, a plurality of columnar portions CL including the stacked film 30a, the semiconductor body 20, and the core film 50 is formed in the stacked body 100.

Incidentally, after forming the memory hole MH, silicon of the substrate 10 may be epitaxially grown on the bottom of the memory hole, so that the lower end portion of the semiconductor body 20 is in contact with the epitaxially grown portion.

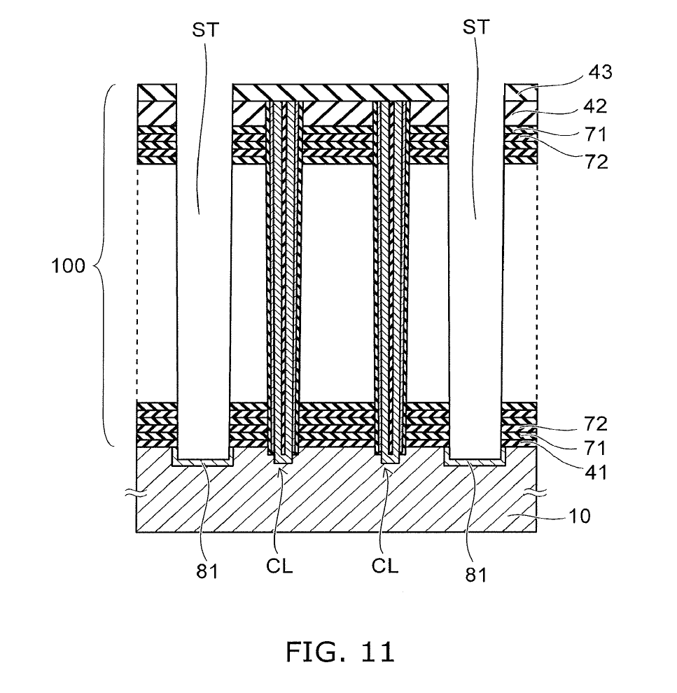

Each film deposited on the insulating film 42 shown in FIG. 10 is removed by chemical mechanical polishing (CMP) or etching back. Thereafter, as shown in FIG. 11, on the insulating film 42, the insulating film 43 is formed. The insulating film 43 covers the upper end of the columnar portion CL.

Then, in the stacked body 100, a plurality of slits ST extending in the stacking direction is formed. The plurality of slits ST is formed in the stacked body 100 including the insulating film 43, the insulating film 42, the sacrifice layer 71, the insulating layer 72, and the insulating film 41 by an RIE method using a mask (not shown). Each slit ST pierces the stacked body 100 to reach the substrate 10.

An impurity is implanted into the substrate 10 exposed on the bottom of the slit ST by an ion implantation method, whereby the semiconductor region 81 is formed on the surface of the substrate 10 on the bottom of the slit ST.

Subsequently, the sacrifice layer 71 is removed by an etching liquid or an etching gas supplied through the slit ST. For example, by using an etching liquid containing phosphoric acid, the sacrifice layer 71 which is a silicon nitride layer is removed.

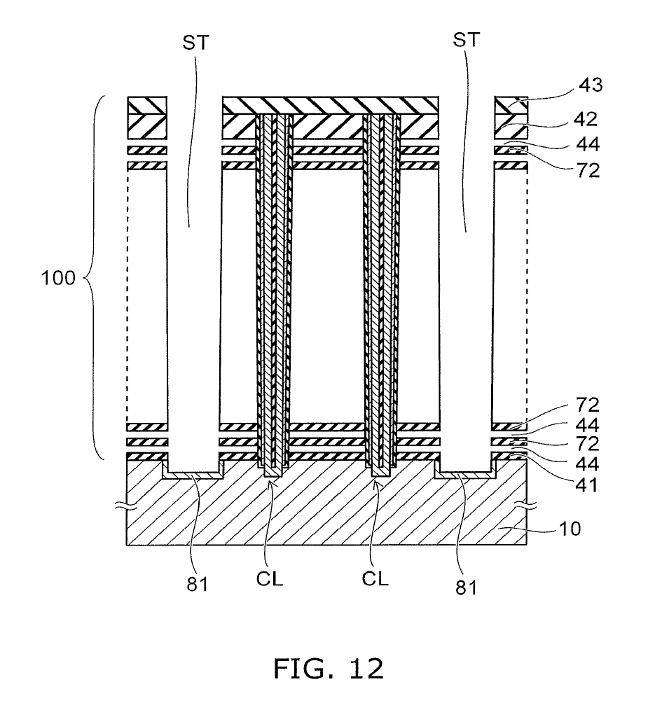

The sacrifice layer 71 is removed, and as shown in FIG. 12 and FIG. 16A, a gap 44 is formed between the insulating layers 72 vertically adjacent to each other. The gap 44 is also formed between the insulating film 41 and the insulating layer 72 being the lowermost layer, and between the insulating layer 72 being the uppermost layer and the insulating film 42. In the gap 44, the upper surface and the lower surface of the insulating layer 72 are exposed.

When etching the sacrifice layer 71, a portion surrounded by the sacrifice layer 71 in the silicon nitride film 33b is protected by the silicon oxide portion 35 as shown in FIG. 16A and is not etched.

The plurality of insulating layers 72 separated in the stacking direction through the gap 44 is supported by the columnar portions CL as shown in FIG. 12. Further, the lower end of the columnar portion CL is supported by the substrate 10, and the upper end thereof is supported by the insulating film 42 and the insulating film 43.

Subsequently, the silicon oxide portion 35 is removed by an etching liquid or an etching gas supplied through the slit ST. As shown in FIG. 16B, the silicon nitride film 33b is exposed in the gap 44.

On the inner wall of the gap 44 (the upper surface and the lower surface of the insulating layer 72 and the side surface of the silicon nitride film 33b), as shown in FIG. 16C, the metal oxide film 33c is formed. A raw material gas of the metal oxide film 33c penetrates into the gap 44 through the slit ST.

The metal oxide film 33c is formed conformally and continuously along the surfaces (the upper surface and the lower surface) facing the gap 44 of the insulating layer 72 and the side surface of the silicon nitride film 33b.

As shown in FIG. 16C, the gap 44 is left inside the metal oxide film 33c between the insulating layer 72 and the insulating layer 72 vertically adjacent to each other. In the gap 44, as shown in FIG. 3A, the conductive layer 70 is formed through the metal nitride film 91.

On the surface exposed in the gap 44 of the metal oxide film 33c, the metal nitride film 91 is formed conformally and continuously. A raw material gas of the metal nitride film 91 penetrates into the gap 44 through the slit ST.

Then, as the conductive layer 70, for example, a tungsten layer or a molybdenum layer is formed by a CVD method. A gas to be used in this CVD penetrates into the gap 44 through the slit ST.

A process of forming, for example, a tungsten layer as the conductive layer 70 by a CVD method includes a process of growing a tungsten initial film which has low crystallinity or is microcrystalline on the surface of the metal nitride film 91, and a process of forming a tungsten layer which has a larger thickness and a larger particle diameter than the initial film inside the initial film.

For example, the initial film is formed by a reaction between tungsten fluoride (WF₆) gas which is a source gas of tungsten and diborane (B₂H₆) gas as a reducing gas. Thereafter, by a reaction between WF₆ gas and hydrogen (H₂) gas as a reducing gas, a tungsten layer is formed inside the initial film.

Also when forming a molybdenum layer as the conductive layer 70, for example, an initial film of molybdenum is formed using a molybdenum fluoride (MoF₆) gas and diborane (B₂H₆) gas, and thereafter, a molybdenum layer can be formed using MoF₆ gas and hydrogen (H₂) gas.

By forming the initial film on the surface of the metal nitride film 91 in the early stage of forming the conductive layer 70, the crystallinity of tungsten or molybdenum to be formed inside the initial film and the crystallinity of the metal nitride film 91 can be divided, and thus, the crystallinity of the metal nitride film 91 does not affect the crystallinity of the conductive layer 70. This promotes an increase in the particle diameter of tungsten or molybdenum by an H₂ reducing reaction to decrease the resistance of the conductive layer 70.

The conductive layer (tungsten layer or molybdenum layer) 70 formed by the CVD method described above also contains fluorine and boron other than the main component metal (tungsten or molybdenum). There is a concern that fluorine (F) contained in the conductive layer 70 diffuses into the columnar portion CL in a post-process accompanied with a heat treatment to be performed after forming such a conductive layer 70. The fluorine can etch the silicon oxide film 33a of the block insulating film 33.

According to the embodiment, the silicon nitride film 33b provided between the conductive layer 70 and the silicon oxide film 33a blocks the diffusion of fluorine from the conductive layer 70 into the silicon oxide film 33a. This suppresses etching of the silicon oxide film 33a and therefore, the performance of blocking the diffusion of electric charges stored in the charge storage film 32 to a side of the conductive layer 70 is not deteriorated.

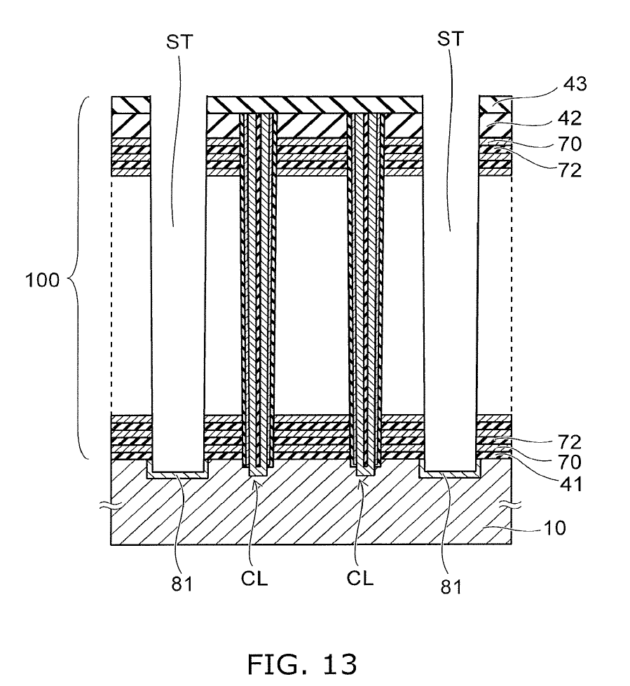

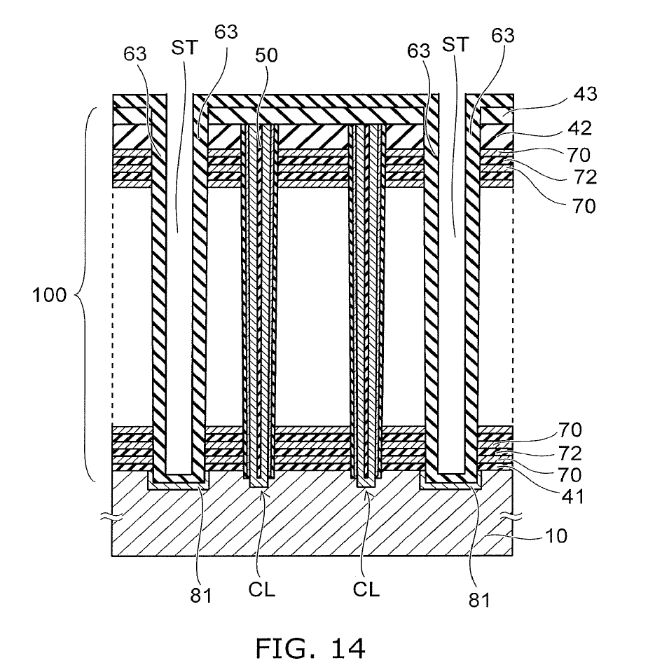

After forming the conductive layer 70 as shown in FIG. 13, the insulating film 63 is formed on the side surface and the bottom of the slit ST as shown in FIG. 14.

After removing the insulating film 63 formed on the bottom of the slit ST by an RIE method, the interconnect portion LI is buried inside the insulating film 63 in the slit ST as shown in FIG. 2. The lower end of the interconnect portion LI is connected to the substrate 10 through the semiconductor region 81. Thereafter, the bit line BL, the source line SL, etc. shown in FIG. 1 are formed.

FIG. 3B shows another structural example in a sectional portion similarly to FIG. 3A.

The above-mentioned silicon oxide portion 35 is left without being removed in the process shown in FIG. 16B. The silicon oxide portion 35 is provided between the metal oxide film 33c provided on the side surface of the conductive layer 70 and the silicon nitride film 33b.

Between the conductive layer 70 and the charge storage film 32, the silicon oxide portion 35 is also provided in addition to the silicon oxide film 33a. Due to this, the performance of blocking the diffusion of electric charges from the charge storage film 32 to a side of the conductive layer 70 can be further enhanced. In addition, by omitting the process of removing the silicon oxide portion 35, the process can be shortened, and the cost can be reduced.

FIG. 3C shows still another structural example in a sectional portion similarly to FIG. 3A.

After forming the gap 44 shown in FIG. 16B, the silicon nitride film 33b may be formed in the gap 44 instead of forming the silicon nitride film 33b on the side surface of the memory hole MH.

In the gap 44, the side surface of the silicon oxide film 33a is exposed. As shown in FIG. 3C, the silicon nitride film 33b is formed conformally and continuously along the surfaces (upper surface and lower surface) facing the gap 44 of the insulating layer 72 and the side surface of the silicon oxide film 33a.

The metal oxide film 33c is formed inside the silicon nitride film 33b, and the conductive layer 70 is formed inside the metal oxide film 33c through the metal nitride film 91. The silicon nitride film 33b is also formed between the conductive layer 70 and the insulating layer 72, and blocks the diffusion of fluorine from the conductive layer 70 into the insulating layer (silicon oxide layer) 72.

Further, the silicon nitride film 33b may be formed in the gap 44 without removing the silicon oxide portion 35.

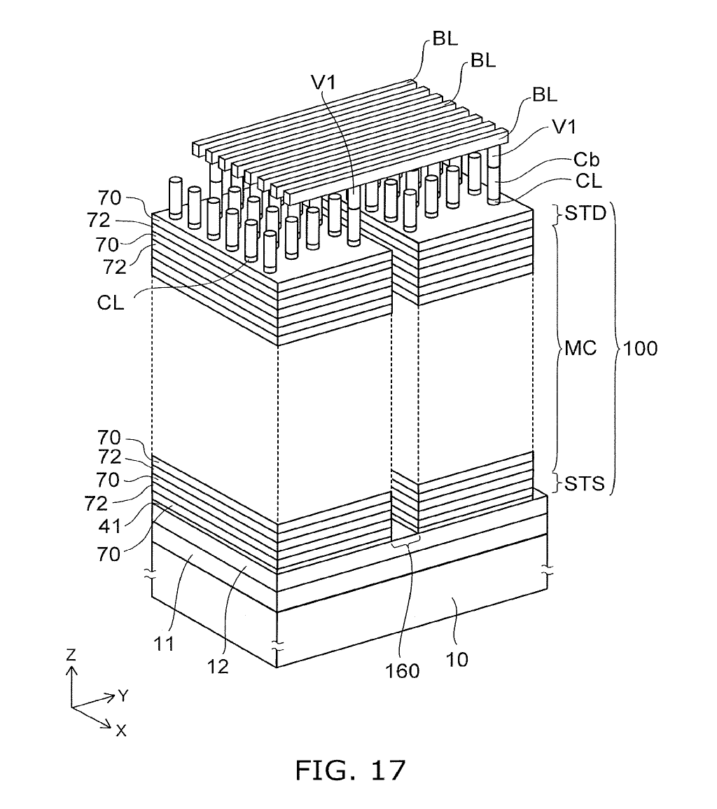

FIG. 17 is a schematic perspective view of another example of the memory cell array of the embodiment.

Between the substrate 10 and the stacked body 100, a first foundation layer 11 and a second foundation layer 12 are provided. The first foundation layer 11 is provided between the substrate 10 and the second foundation layer 12, and the second foundation layer 12 is provided between the first foundation layer 11 and the stacked body 100.

The second foundation layer 12 is a semiconductor layer or a conductive layer. Alternatively, the second foundation layer 12 may include a stacked film of a semiconductor layer and a conductive layer. The first foundation layer 11 includes a transistor and an interconnect for forming a control circuit.

The lower end of the semiconductor body 20 of the columnar portion CL is in contact with the second foundation layer 12, and the second foundation layer 12 is connected to the control circuit. Therefore, the lower end of the semiconductor body 20 of the columnar portion CL is electrically connected to the control circuit through the second foundation layer 12. That is, the second foundation layer 12 can be used as a source layer.

The stacked body 100 is divided into a plurality of blocks (or finger portions) in the Y-direction by a dividing portion 160. The dividing portion 160 is an insulating film, and does not include an interconnect.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a foundation layer;
a stacked body provided above the foundation layer, the stacked body including a plurality of conductive layers stacked with an insulator interposed;
a semiconductor body extending in the stacked body in a stacking direction of the stacked body;
a charge storage portion provided between the semiconductor body and one of the conductive layers;
a silicon oxide film provided between the charge storage portion and the one of the conductive layers; and
a silicon nitride film provided between the silicon oxide film and the one of the conductive layers.

2. The device according to claim 1, further comprising a metal oxide film provided between the one of the conductive layer and the silicon nitride film.

3. The device according to claim 1, further comprising a silicon oxide portion provided between the one of the conductive layers and the silicon nitride film.

4. The device according to claim 2, further comprising a silicon oxide portion provided between the metal oxide film and the silicon nitride film.

5. The device according to claim 1, wherein the silicon nitride film extends continuously in the stacking direction.

6. The device according to claim 2, wherein the metal oxide film is also provided between the one of the conductive layers and the insulator.

7. The device according to claim 6, further comprising a metal nitride film provided between the one of the conductive layers and the metal oxide film.

8. The device according to claim 1, wherein the conductive layers are metal layers containing tungsten or molybdenum as a main component.

9. The device according to claim 1, wherein the conductive layers contain fluorine.

10. A method for manufacturing a semiconductor device, comprising:
forming a stacked body above a foundation layer, the stacked body including a plurality of first layers and a plurality of second layers, the first layers and the second layers including a first layer and a second layer stacked alternately; and
forming a columnar portion in the stacked body, the columnar portion extending in a stacking direction of the stacked body, the columnar portion including a semiconductor body extending in the stacking direction, a charge storage portion provided between the first layer and the semiconductor body, a silicon nitride film provided between the first layer and the charge storage portion, and a silicon oxide film provided between the silicon nitride film and the charge storage portion.

11. The method according to claim 10, further comprising replacing the first layer with a conductive layer after forming the columnar portion.

12. The method according to claim 11, wherein as the conductive layer, a tungsten layer or a molybdenum layer is formed by a CVD method using a gas containing tungsten fluoride or molybdenum fluoride.

13. The method according to claim 11, wherein the replacing the first layer with the conductive layer includes
removing the first layer through a slit formed in the stacked body, thereby forming a gap communicating with the slit between the second layers, and
forming the conductive layer in the gap.

14. The method according to claim 13, wherein
the first layer is a silicon nitride layer, and the second layer is a silicon oxide layer, and
the method further comprises forming a silicon oxide portion provided between the first layer and the silicon nitride film.

15. The method according to claim 14, wherein after removing the first layer, the silicon oxide portion is removed, and the conductive layer is formed in the gap.

16. The method according to claim 14, wherein after removing the first layer, the conductive layer is formed in the gap while leaving the silicon oxide portion.

17. The method according to claim 13, further comprising forming a metal oxide film in the gap before forming the conductive layer.

18. A method for manufacturing a semiconductor device, comprising:
forming a stacked body above a foundation layer, the stacked body including a plurality of first layers and a plurality of second layers, the first layers and the second layers including a first layer and a second layer stacked alternately;
forming a columnar portion in the stacked body, the columnar portion extending in a stacking direction of the stacked body, the columnar portion including a semiconductor body extending in the stacking direction, a charge storage portion provided between the first layer and the semiconductor body, and a silicon oxide film provided between the first layer and the charge storage portion;
forming a gap between the second layers by removing the first layer after forming the columnar portion; and
forming a conductive layer in the gap with a silicon nitride film interposed.

19. The method according to claim 18, further comprising forming a metal oxide film on a surface of the silicon nitride film in the gap.

20. The method according to claim 18, wherein as the conductive layer, a tungsten layer or a molybdenum layer is formed by a CVD method using a gas containing tungsten fluoride or molybdenum fluoride.
